(19) United States
(12) Patent Application Publication
(10) Pub. No.: US 2022/0111562 A1
(43) Pub. Date: Apr. 14, 2022

(54) METHOD FOR PRODUCING A STRUCTURE HAVING AT LEAST ONE CURVED PATTERN

(71) Applicant: COMMISSARIAT A L'ENERGIE ATOMIQUE ET AUX ENERGIES ALTERNATIVES, Paris (FR)

(72) Inventors: Hubert TEYSSEDRE, Grenoble Cedex 09 (FR); Pierre BRIANCEAU, Grenoble Cedex 09 (FR); Stefan LANDIS, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/262,095

(22) PCT Filed: Jul. 23, 2019
(86) PCT No.: PCT/EP2019/069829

§ 371 Date: Jan. 21, 2021

(30) Foreign Application Priority Data
Jul. 25, 2018 (FR) 18 56929

(51) Int. Cl. B29C 33/38; G02B 3/00; G03F 7/00; B29D 11/00

(52) U.S. Cl. CPC B29C 33/3842; B29D 11/00365; G03F 7/0002; G02B 3/0031

(57) ABSTRACT

A method for producing a structure having at least one curved pattern includes providing a substrate having a front face, where one portion is structured by at least one plurality of reliefs, the reliefs of each plurality defining spaces therebetween, and another portion is free of reliefs. The method also includes depositing a base layer of a material such as a polymer or a glass, on the front face of the substrate, at least in line with the reliefs, and allowing the material of the base layer to at least partially fill the at least one of the spaces by deformation. The base layer is thus deformed so that its free surface has at least one curved pattern.

### TECHNICAL FIELD OF THE INVENTION

The invention generally relates to the production of structures of micrometric or nanometric size, to form microelectronic, optical or optoelectronic devices, as well as micromechanical or electromechanical devices. An advantageous application of the invention relates to the field of methods for manufacturing a master for the manufacture of at least a portion of a nanoimprint mould.

More particularly, the invention finds a particularly advantageous application in the manufacture of a master for forming moulds or mould parts, in order to mould aspherical microlenses, advantageously of low, or even very low curvature. These microlenses can in turn be intended for applications of light collection, imaging and light guiding, in transmission or in reflection, for example.

An advantageous application of the invention relates to the field of methods for manufacturing at least a portion of a nanoimprint mould.

Another application of the present invention is to directly manufacture a microlens, optionally without implementing any one of a mould part and a master.

### PRIOR ART

There are many techniques for manufacturing microlenses.

Among these techniques, micro-jet imprinting and thermal creep are now very advanced techniques that are used in industry to produce high optical quality microlenses. These techniques are more qualitative than quantitative when it comes to achieving an accurate surface profile. For example, the thermal creep of photo-resin (See for example the article by N. T. Gordon and al., entitled “Application of microlenses to infrared detector arrays”, in the journal Infrared Phys., 30, 6, 599-604, 1991) and imprinting by micro-jets are based on delicate physicochemical phenomena involving a balancing of the surface tensions involved, which greatly limits the choice of surface profiles potentially obtained by these techniques.

On the contrary, laser ablation (See, for example, the article by F. Chen and al., Entitled “Simple fabrication of closed-packed IR microlens arrays on silicon by femtosecond laser wet etching”, in the journal Applied Physics A, (2015) 121: 157-162), two-photon polymerisation and direct laser writing techniques allow to obtain a very large choice of surface profiles. However, these techniques are sequential, which does not make them adapted in terms of cost and efficiency on an industrial scale.

The use of RIE (for “reactive ion etching”) etching (See for example the article by R. Yamazaki and al., entitled “Microlens for uncooled infrared array sensor”, in the journal Electronics and Communications in Japan, 96, 2, 2013) and the use of proton lithography are, in turn, considered to be expensive techniques, especially if they are used to produce polymer microlenses.

More recently, moulding and imprinting techniques such as those generally referred to by their names “hot embossing”, “imprinting” and “injection moulding” have been increasingly used to produce microlenses. The principle of manufacture is to fill a mould with a material (typically a polymer) and detach the material from the mould. The microlenses potentially obtained in this way can be hemispherical or spherical in shape. Depending on the type of substrate on which the moulding is made, silicon or glass (or quartz) substrate, the applications may concern, respectively, the wavelength range of infrared (IR) or that of visible light.

The manufacturing methods by imprinting require the availability of moulds which can, in turn, be manufactured for example using the techniques mentioned in the following publication: “Journal of Optics A: Pure and Applied Optics 8”, issue 7, pages 407-429, published in 2006. As a general rule, the standard techniques implemented by the microelectronics industry are most often preferred, because they are very reliable and the integration of the microlenses into the final components, typically electronic components of transistor type, is facilitated.

A known method for manufacturing a mould by microelectronic techniques is described below with reference to FIGS. 1A, 1B and 1C which show sectional views illustrating some steps of the method. After depositing a thermal silicon (SiO₂) or silica oxide layer 1001, on a silicon sheet 1000 of the type of those commonly used by the microelectronics industry, that is to say a silicon wafer with a large diameter, for example with a diameter of 8 inches, a silicon nitride (Si3N4) layer 1002, for example with a thickness of 350 nanometres, is deposited on the thermal oxide layer 1001. A pattern 1003 is etched into the nitride layer 1002 by conventional lithography steps. Since the nitride layer 1002 acts as a hard mask, the sheet is immersed in a wet etching solution; a solution of hydrofluoric acid (HF) is particularly adapted here. As illustrated in FIG. 1B, the nitride mask 1002 protects the areas of the sheet where the etching solution must not attack the thermal oxide 1001. The etching of the thermal oxide layer 1001 is isotropic, thus forming a cavity in the shape of a sphere portion centred on the pattern 1003. In the next step, the result of which is illustrated in FIG. 1C, the nitride mask 1002 is removed and, after an anti-adhesive treatment, the sheet obtained 1004 can be used as a mould for imprinting.

Optionally, the relief patterns of the mould can be created directly in the silicon 103 without resorting to the intermediate silica layer 102. In this case, the etching solution is a mixture of hydrofluoric acid (HF) and nitric acid (HNO3) as reported in 2009 in an article in the journal Optics Express, Volume 17, Edition 8, pages 6283 to 6292 (2009).

If the mould manufacturing methods briefly described above are suitable for obtaining, as shown, spherical or hemispherical patterns, it is on the other hand difficult to obtain lenses called aspherical lenses of desired shapes or lenses with large radii of curvature (diameter very much greater than the sweep) with these methods. However, the production of masters of aspherical microlenses is generally required in many applications. These aspherical lenses indeed usually have much better optical properties. In particular, the spherical lenses, unlike aspherical lenses, induce optical aberrations, the rays passing through the centre of the lens not converging at exactly the same point as those passing through the edges. This causes blurring at large apertures and a widening of the focus spot that cannot be ignored in most applications.

It is then necessary to use lasers and techniques called “laser machining” or laser ablation, already mentioned above, which alone are likely to be able to create the necessary complex profiles with, however, the major disadvantage that each microlens must then be individually shaped. These techniques are for example described in the article “Spherical and Aspheric Microlenses Fabricated by Excimer Laser LIGA-like Process”, by Yung-Chun Lee, and al., Published in 2006 in the journal “Journal of Manufacturing Science and Engineering”, 129, 126-134.

An object of the present invention is therefore to provide a method for producing a structure having at least one curved pattern which allows to limit, or even eliminate, at least some of the problems set out above.

The other objects, features and advantages of the present invention will become apparent upon examining the following description and the accompanying drawings. It is understood that other advantages can be incorporated.

### SUMMARY OF THE INVENTION

To achieve this purpose, according to one embodiment, the present invention provides a method for producing a structure having at least one pattern, for example to manufacture a master for a nanoimprint mould, the method comprising the following steps:
Providing a substrate having a front face whereof:
   one portion is structured by at least one plurality of reliefs, the reliefs of each plurality defining therebetween at least one space, preferably at least two spaces, and
   another portion is free of reliefs,
Depositing a base layer, preferably of uniform thickness, of a material based on one of a polymer and a glass, on the front face of the substrate, at least in line with the reliefs, or even in line with the entire front face of the substrate, the base layer having a first face facing the front face of the substrate and a second face opposite the first face, and
Allowing the material of the base layer to at least partially fill the at least one space, preferably all the spaces, defined between the reliefs of the same plurality by deformation of the base layer.
   The base layer is thus deformed so that its second face forms a structure having at least one curved pattern in line with the at least one space which is at least partially filled with the material of the base layer.

Thus, the free surface of the base layer is deformed due to the at least partial filling of the spaces between the reliefs of each plurality. The volume of material displaced in particular in line with the reliefs during the deformation of the base layer is at most equal to the volume of the spaces defined between the reliefs. By applying conventional microelectronic techniques, it is possible to perfectly control the volume of these spaces. Consequently, the volume of material displaced is a fortiori also well controlled; however, the shape, the curvature and the sweep of the formed pattern depend in particular on the volume of the displaced material. The shape, the curvature and the sweep of the formed pattern are therefore perfectly controllable.

The pattern thus formed can advantageously have an aspherical curvature, which is preferably low (<10⁻² μm⁻¹), or even very low (<10⁻⁶ μm⁻¹).

Thanks to the method according to the invention, it is possible to manufacture a nanoimprint mould. This mould can then be used for moulding microlenses which have an aspherical curvature, which is preferably low (<10⁻² μm⁻¹), or even very low (<10⁻⁶ μm⁻¹).

Furthermore, the manufacturing method as introduced above is advantageously simple, rapid, operable in a single series of steps on the scale of a wafer, and compatible with the standard techniques of microelectronics.

Another aspect of the present invention relates to a method for manufacturing at least one nanoimprint mould using a master manufactured by implementing the method as introduced above. Thus, the present invention provides for the use of a master manufactured by implementing the method as introduced above, for the manufacture of at least one nanoimprint mould.

Another aspect of the present invention relates to a method for manufacturing at least one microlens by nanoimprinting, using a nanoimprint mould manufactured by transferring at least one pattern from a master manufactured by implementing the method as introduced above. Thus, the present invention provides for the use of a nanoimprint mould manufactured by transferring at least one pattern from a master manufactured by implementing the method as introduced above, for the manufacture of at least one microlens per nanoimprint.

Another aspect of the present invention relates to a method for manufacturing at least one nanoimprint mould part manufactured by implementing the method as introduced above. The present invention provides for the use of the nanoimprint mould part manufactured by implementing the method as introduced above, for the manufacture of at least one microlens by nanoimprinting from said part.

Another aspect of the present invention relates to a method for manufacturing a lens, or microlens, by implementing the method as introduced above. This other aspect of the invention is in particular advantageous for reflective optics applications. For this purpose, provision can indeed be made to make the polymer, on the basis of which the base layer is made, reflective by depositing on the polymer, at low temperature, a metal or dielectric thin layer, so as to optimise the reflection.

### BRIEF DESCRIPTION OF THE FIGURES

The purposes, objects, as well as the features and advantages of the invention will become more apparent from the detailed description of an embodiment thereof which is illustrated by the following accompanying drawings wherein:

FIGS. 1A, 1B and 1C schematically show some steps of a method for manufacturing a mould for imprinting microlenses according to the prior art.

FIG. 2 schematically shows a sectional view of a microlens as the present invention aims at allowing to manufacture.

FIGS. 3A to 3I schematically show various sectional views illustrating the steps of the method for manufacturing a concave pattern according to one embodiment of the invention.

FIGS. 4A-4D schematically show some of the various steps of the method for manufacturing a convex pattern according to one embodiment of the invention.

FIGS. 5A and 5B each schematically show a perspective view of at least a portion of a structured substrate according to one embodiment of the invention.

FIG. 6 is a flowchart of the method for producing a structure according to one embodiment of the invention.

FIGS. 7A, 7B and 7C schematically show a first exemplary embodiment of the method for producing a structure according to the invention.

FIG. 8A schematically shows a second exemplary embodiment of the method for producing a structure according to the invention comprising two patterns.

FIG. 8B shows a graph showing the profiles of the two patterns resulting from the second exemplary embodiment and measured by a stylus.

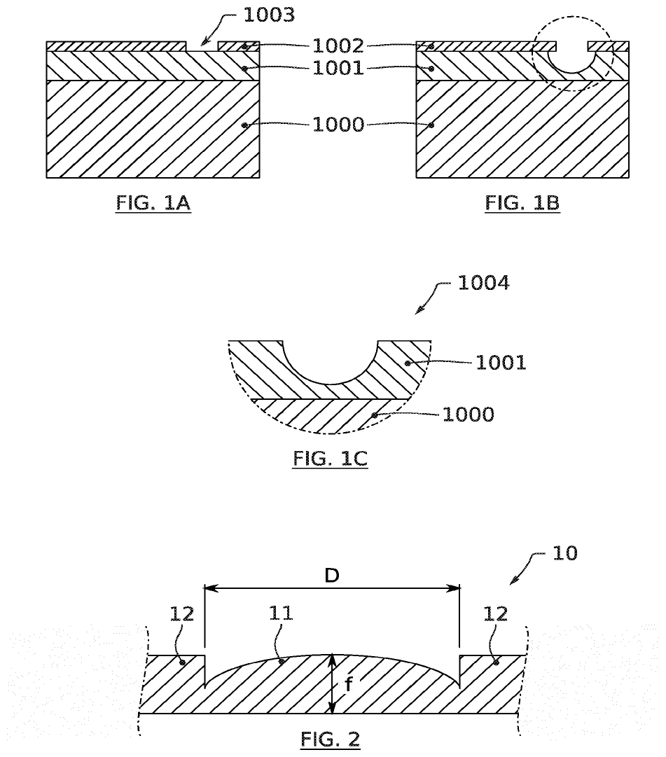

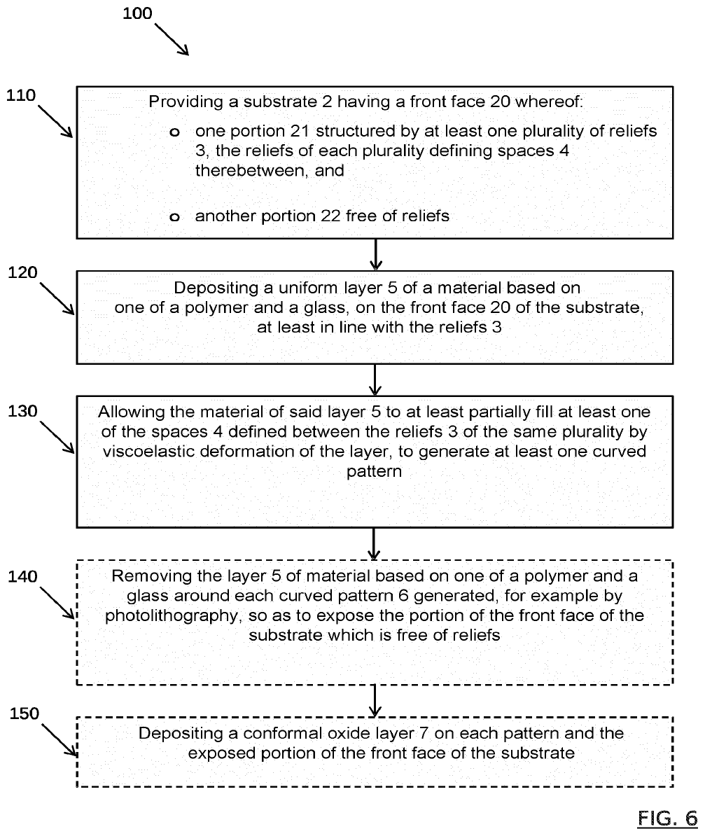

The drawings are given by way of examples and are not limiting of the invention. They constitute schematic principle representations intended to facilitate the understanding of the invention and are not necessarily on the scale of practical applications. In particular, the relative dimensions of the various layers and reliefs are not representative of reality. In FIG. 6, the steps of the method framed by dashed lines may only be optional.

### DETAILED DESCRIPTION OF THE INVENTION

Before starting on a detailed review of embodiments of the invention, optional features which can possibly be used in combination or alternatively are listed below:
The deformation is viscoelastic; it can also be plastic, in particular for a base layer 5 comprising a polymer. A plastic deformation of the polymer of the base layer can effectively be obtained, for example by pressurising the assembly, so as to induce stresses and go beyond the plasticity threshold of the polymer;
the deposition of the base layer can be carried out under vacuum, and the step of at least partially filling the at least one space defined between the reliefs of the same plurality can be carried out at ambient pressure, preferably under a flow of compressed air or nitrogen;
the base layer being further deformed so that the distance from the second face of the base layer to the bottom of the reliefs of each plurality is always less than this distance before deformation;
for each plurality of reliefs, the number, shape and spatial distribution of the reliefs are configured at least depending on viscoelastic or plastic parameters of the base layer and deposition parameters of the base layer. A determined curvature of the pattern is thus obtained. It is thus advantageously provided by the method according to the invention to obtain an almost infinite variety of curved patterns by varying parameters which are otherwise well, or even perfectly, controlled;
the step of at least partial filling the at least one space defined between the reliefs of the same plurality can comprise the following step: Completely filling each space until a pattern, the curvature of which is determined by balancing the surface tensions involved, is generated. If the evolution of the pattern is relatively predictable and the voluntary stopping of this relatively well controlled evolution, this nevertheless complicates the method. It is advantageously easier to let the base layer flow until the balance shape of the curved pattern is obtained;
the step of at least partially filling the at least one space defined between the reliefs of the same plurality may comprise a rise in temperature, at least 10°, preferably between 10 and 40° C., above the glass transition temperature T_{g} of the material from which the base layer is made.
the at least one plurality of reliefs can define at least one cavity formed in the front face of the substrate. The curved pattern thus formed may be concave;
the at least one plurality of reliefs can comprise a mesa formed on the front face of the substrate and the at least one space can comprise at least one cavity formed in the mesa;
the at least one plurality of reliefs can comprise at least one relief protruding from the front face of the substrate. The pattern thus formed can be convex;
the method may comprise, where appropriate, the following step: allowing the material of the base layer located in line with the portion of the front face of the substrate which is free of reliefs to contact at least a portion of the front face of the substrate. In addition or alternatively, with at least two pluralities of reliefs structuring the front face of the substrate and defining second spaces therebetween, the method further comprises the following step: allowing the material of said base layer located in line with a portion of the front face of the substrate which is free of reliefs to at least partially fill at least a second space, preferably each second space, each second space being larger, for example at least ten times larger, than the at least one space defined between the reliefs of the same plurality;
the at least one plurality of reliefs can be formed by at least one etching step, for example by photolithography, of the front face of the substrate;
the method may further comprise, once said at least one pattern has been formed, the following step:
   Stiffening, at least on the surface, the base layer, the stiffening step comprising, where appropriate, a corresponding one from:
   providing the polymer, at least on the surface of the base layer, in a glassy, solid or rubbery state, and
   providing the glass, at least on the surface of the base layer, in a glassy state;
the method may further comprise, once said at least one pattern has been formed, the following steps:
   Removing the base layer around each formed pattern, for example by photolithography, so as to expose the portion of the front face of the substrate which is free of reliefs, then
   Depositing a finish layer over each pattern and the exposed portion of the front face of the substrate.
The master is thus advantageously ready to be used in order to obtain a mould, in particular by steps comprising the grafting on the finish layer of non-stick layers and the transfer of the pattern in transfer layers generally composed of organic elements and intended to form an intermediate mould;
the at least one plurality of reliefs can define a cavity and/or comprise a relief having at least one of:
   a depth or height greater than 10 μm, preferably greater than 100 μm, for example equal to 180 μm, and
   at least one transverse dimension comprised between 20 and 200 μm, preferably comprised between 50 and 100 μm.
At least one relief of each plurality preferably has at least one size dimension less than 1 mm;
the at least one space defined between the reliefs of each structured portion of the front face of the substrate can take one of:
   the shape of a hole, whether through or blind, of circular or oblong section and
   the shape of a circular or linear groove.
The techniques of microelectronics allow to consider patterns of various sizes and shapes allowing to obtain an almost infinite variety of curved patterns;
the at least one space defined between the reliefs of each structured portion of the front face of the substrate occupies at least half of the surface of this structured portion. Alternatively or in addition, for the same plurality of reliefs, a distance between two reliefs adjacent to each other, or else between each pair of reliefs adjacent to each other, is provided which is at least equal to a smaller transverse dimension of at least one relief of the plurality;
the step of depositing the base layer can be configured so that the base layer has, preferably before its deformation, a thickness comprised between 20 and 200 μm;
the step of depositing the base layer may comprise one of the steps among:
   Depositing a dry film by lamination, and
   Depositing a solution comprising the base layer material by centrifugal coating.

These base layer deposition techniques are advantageously simple, rapid and operable in a single step or series of steps at the scale of a wafer;
the at least one plurality of reliefs comprises several pluralities of reliefs spaced apart by the portion of the front face of the substrate which is free of reliefs, each plurality of reliefs being intended for the formation of a pattern, and preferably of a single pattern;
the at least one of the portion of the front face of the substrate which is free of reliefs and the step of depositing the base layer can be configured so that the deformation of the base layer at each plurality of reliefs does not influence the deformation of the base layer at any other plurality of reliefs;
the structure can be a master for the production of a nanoimprint mould; as a first alternative, the structure can be a part of a nanoimprint mould; as a second alternative, the structure can be a lens.

It is specified that in the context of the present invention, the term “on”, “surmounts”, “covers” or “underlying” or their equivalents do not necessarily mean “in contact with”. Thus, for example, the deposition of a first layer on a second layer does not necessarily mean that the two layers are directly in contact with one another, but this means that the first layer at least partially covers the second layer by being either directly in contact therewith, or by being separated therefrom, for example by at least one other layer or at least one other element.

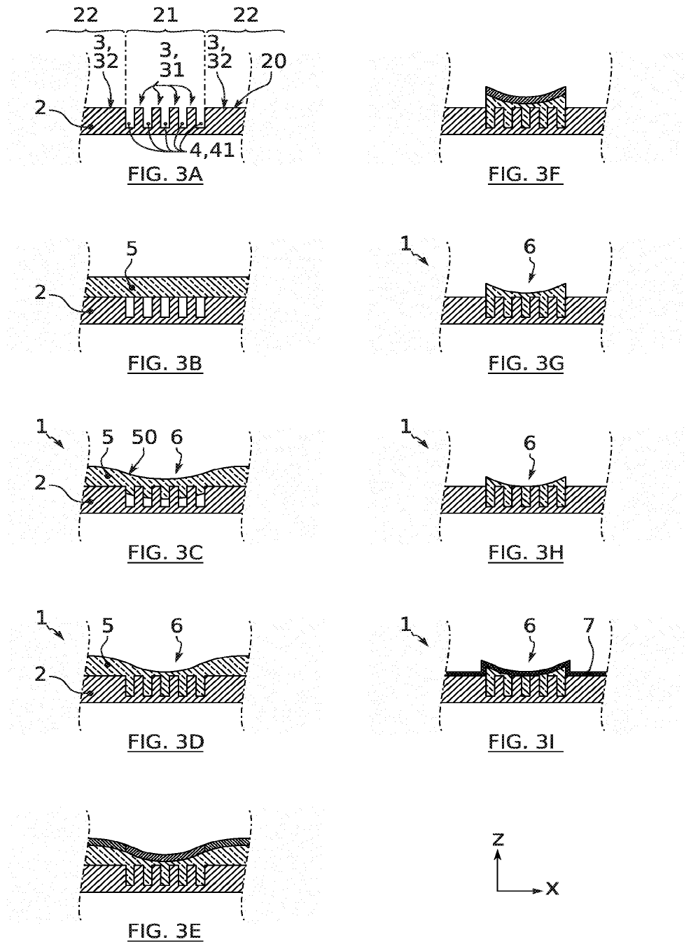

In the context of the present invention, the thickness of a layer, as well as the depth or the height of a cavity or of a relief is taken in a direction perpendicular to a front face of a substrate on which the layer rests or at which the cavity or relief is formed. The thickness, height and depth are thus taken in a direction perpendicular to the main plane wherein the substrate and the layer extend. In the figures, the thickness, height and depth are taken in the direction Z as illustrated in FIG. 3; and any transverse dimension, for example that of a pattern, a cavity or a relief is taken in a direction X, as illustrated in FIG. 3, perpendicular to the direction Z.

Likewise, when it is indicated that a material is deposited in line with at least a portion of a substrate, this means that this material and at least this portion of the substrate are both located on the same line perpendicular to the main plane of the substrate, in other words on the same line oriented vertically in the figures.

In the context of the present invention, the term “pattern” denotes a local variation of a free surface of a base layer having an analogue profile, that is to say with a continuous variation of the tangents of the profile shape, as illustrated for example in FIGS. 2, 3C, 3D, 3I, 4C, 4D, 7A, 7C and 8B.

“Nanoimprinting” means any lithography technique wherein a hard mould is applied to the surface of a material, in order to leave therein, in a resin, or equivalently a polymer, the imprint of a structure of a micrometric or even a nanometric size.

“Master” means an element bearing an imprint or pattern that is in negative in a mould obtained by direct copying of the master. Thus, the master has at least one pattern which is reproduced in negative in the mould. The mould is then used to transfer this negative to another layer, for example to form a microlens. The pattern formed in this other layer corresponds to the negative of the pattern carried by the mould. Advantageously, the pattern carried by the same mould is transferred to a very large number of layers.

A film or a layer based on a material A, means a film or a layer comprising this material A and possibly other materials.

A layer of “uniform” thickness means a layer having a constant thickness in a direction perpendicular to the tangent at each point of one of its two main faces.

“Conformal” means a layer geometry which has the same thickness, within manufacturing tolerances, despite changes in layer direction, for example at the sidewalls of a pattern.

“Microlens” means a small lens, generally with a diameter less than 5 mm, or even less than or equal to 2 mm, and which may reach around ten micrometres, and one of the dimensions (diameter or sweep) of which is less than 1 mm.

The present invention can allow to directly or indirectly manufacture microlenses such as that 10 illustrated in FIG. 2. Each microlens 10 thus manufactured can advantageously have an aspherical curvature 11, and in particular a curvature with a low (<10⁻² μm⁻¹), or even a very low (<10⁻⁶ μm⁻¹) curvature. More particularly, it has a transverse dimension D greater than 10 μm and less than 5 mm, for example equal to 2 mm, for a sweep f greater than 1 μm and less than 300 μm, for example equal to 100 μm. The sweep f is measured in a direction perpendicular to the transverse dimension of the microlens. Typically, f and D are measured along the axes Z and X respectively. Each microlens 10 can further comprise extensions 12, located on either side of or around the curvature 11. These extensions 12 can serve, where appropriate, as alignment marking areas. As will appear subsequently, these extensions 12 are advantageously naturally derived from the implementation of the method according to the invention and therefore do not require any particular additional treatment to be carried out.

A first embodiment of the invention is described below with reference to FIGS. 3A to 3I and FIG. 6.

This first embodiment describes in particular a method 100 for manufacturing a master 1 for a nanoimprint mould, but it is understood that the description which is given below also applies mutatis mutandis to describe a method 100 for manufacturing a part of a nanoimprint mould and/or a method 100 for manufacturing a lens. These three variations of the method for producing a structure 1 having at least one curved pattern 6 indeed provide, for the first one, for the production of a master for a nanoimprint mould as structure 1, for the second one, for the production of a part of a nanoimprint mould as structure 1, and, for the third one, for the production of a lens as structure 1.

With reference to the aforementioned figures, the method 100 for manufacturing the master 1 for a nanoimprint mould first comprises a step of providing 110 a structured substrate 2.

The substrate 2 is for example based on a material selected from: silicon, germanium, glass, silicon nitride, etc. More generally, the substrate 2 is selected from a material which, on the one hand, can be structured as described below and which, on the other hand, withstands the temperatures and other stresses undergone during the implementation of the method according to the invention. This last stress is not strongly limiting given that the temperatures to which the substrate 2 will be subjected during the method 100 according to the invention are generally not necessarily high. Typically, for a pattern created from a layer of polymer, such as a resin, the temperatures to which the substrate is subjected do not exceed 400° C.

In the exemplary embodiments described below, the substrate comprises a silicon wafer, which may have a diameter of eight inches, or even more. As will be seen below, such a wafer advantageously offers a sufficient working surface to manufacture several masters in a single implementation of the method according to the invention.

More particularly, the substrate 2 comprises a front face 20 which is partly and preferably only partly structured. Thus, the front face 20 of the substrate comprises, or consists of, at least one structured portion 21 and another unstructured portion 22.

Each structured portion 21 comprises a plurality of reliefs 3 which define spaces 4 therebetween. On the same substrate 2, several structured portions 21 can be provided each comprising a plurality of reliefs 3 which is specific thereto. The other portion 22 of the front face 20 of the substrate 2 is free of reliefs. It is preferably substantially flat. When several pluralities of reliefs 3 are provided, each occupying a structured portion 21 of the front face 20 of the substrate 2, the other portion 22 of the front face 20 can extend integrally around each structured portion 21 and around the assembly formed by the plurality of structured portions. Thus, each structured portion can be surrounded on all sides by a portion 22 of the front face 20 of the substrate 2 which is free of reliefs. Consequently, at least two pluralities of reliefs 3 structuring the front face of the substrate define second spaces therebetween. Each second space is larger, for example at least ten times larger, than the space defined between the reliefs 3 of the same plurality. In general, the structuring of the front face 20 of the substrate 2 is preferably carried out using known methods in microelectronics, such as photolithography, and more particularly the deep relief microelectronic manufacturing methods (for example hard mask and method Bosch®).

As shown in FIG. 3A, the structuring of the front face 20 of the substrate 2 comprises the formation of a plurality of reliefs 3, 31 forming therebetween cavities 41 in the front face 20 of the substrate. As will be seen below, the invention is not limited to this method for structuring the front face of the substrate.

Each cavity 41 may have a height, or more particularly here a depth, greater than 10 μm, preferably greater than 100 μm. Each cavity 41 can also have at least one transverse dimension comprised between 20 and 200 μm, preferably comprised between 50 and 100 μm. Each cavity 41 can be in the shape of a hole, for example of circular section; in which case, the transverse dimension of the cavity 41 corresponds to its diameter. When a cavity 41 forms a hole, the latter may be through or blind. Alternatively or in addition, each cavity 41 can be in other shapes, such as the shape of a hole of oblong or polygonal, for example rectangular or square section, the shape of a groove closed or not on itself and crossing or not at least one other groove.

The plurality of reliefs 3 as illustrated in FIG. 3A can conceptually comprise a plurality of reliefs 31, as well as, on either side of the plurality of reliefs 31, reliefs 32 extending to the edge of the substrate 2 or up to another plurality of reliefs.

The reliefs 31 as illustrated in FIG. 3A have dimensions substantially equal to those of the cavities 41 mentioned above. While the invention is not limited to this exemplary embodiment, it is on the other hand preferred that the reliefs 31 be at least of a size guaranteeing them sufficient mechanical strength. Thus, the reliefs 31 preferably have transverse dimensions comprised between 20 and 200 μm, preferably between 50 and 100 μm. Moreover, their height can only be limited by the thickness of the substrate 2.

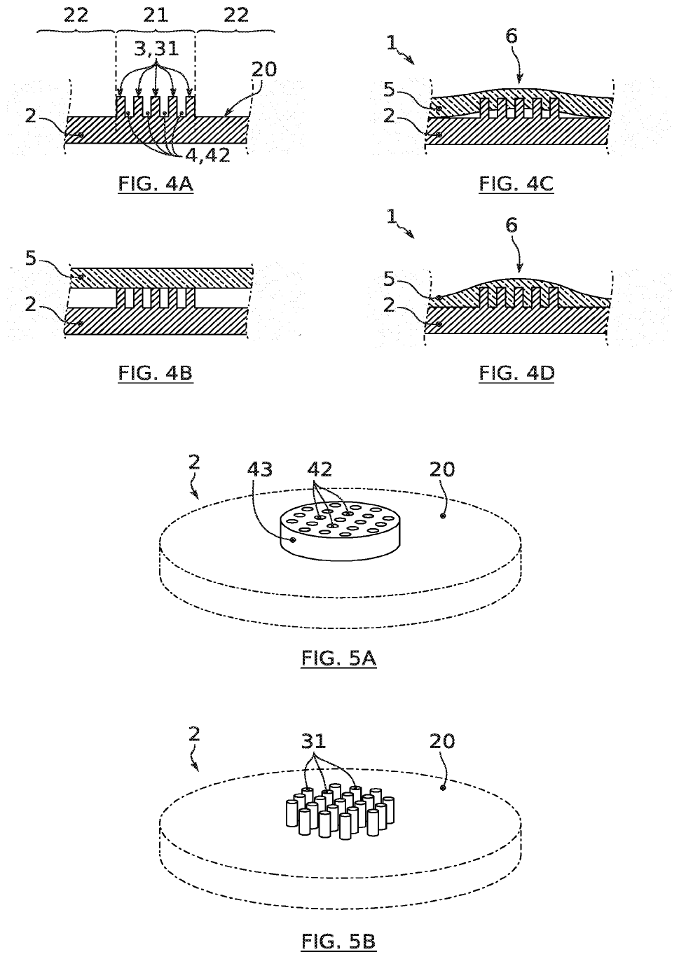

In general, it may be preferable for the structuring of the front face 20 of the substrate 2 to be configured so that the spaces 4, 41 (and 42, See FIG. 4A) defined between the reliefs 31 of each plurality do not extend over less than half of the surface of the corresponding structured portion 21. This stress is generally respected if, for the same plurality of reliefs 3, the structuring of the front face of the substrate 2 comprises the provision of a distance between two reliefs adjacent to each other, or else between each pair of reliefs adjacent to each other, such that said distance is at least equal to a smaller transverse dimension of at least one relief of the plurality.

The structuring of the front face 20 of the substrate 2 can therefore be advantageously carried out by well-known and controlled microelectronic techniques, and of industrial efficiency because they allow the entire front face 20 of the substrate 2 to be treated at once.

Once the structured substrate 2 has been provided 110, the manufacturing method 100 according to the invention comprises a step of depositing 120 a base layer 5 on the front face 20 of the substrate 2.

Preferably, this base layer 5 is formed from a material based on one of a polymer, such as a resin, and a glass. It should be noted here that a polymer and a glass have in common that they can be viscoelastically deformed, in particular when they are brought above their glass transition temperature T_{g}. Glass, generally stiffer than a polymer, will be preferred for the manufacture of patterns 6 of lower curvature. Other materials may be considered which are known to be deformable in this way, and within temperature ranges compatible with maintaining the integrity of the substrate 2.

The base layer 5 is more particularly deposited at least in line with the reliefs 3 of each plurality; it preferably extends beyond said reliefs for reasons which will be explained below when the notion of mesh size is introduced. Thus, in a non-limiting manner, the base layer 5 can extend in line with the entire front face 20 of the substrate 2. The deposition 120 of the base layer 5 is performed so that, at least before its deformation, the base layer 5 has a thickness for example comprised between 20 and 200 μm.

It is preferable that the base layer 5 as deposited 120, and before its deformation, is uniform; its thickness is constant over its entire extent, within manufacturing tolerances. In this way, the shape of the pattern 6 formed can be better, or more easily, controlled, insofar as it is then not necessary to integrate into the method according to the invention, the management of the influence that would, a non-uniformity, and in particular a variation in thickness, of the base layer 5 as deposited 120, have on the shape of the formed pattern 6.

The step 120 of depositing the base layer 5 can comprise either one of the following steps:
Depositing a dry film by lamination, and
Depositing a solution comprising the material of the base layer 5 by centrifugal coating.

The deposition 120 of the base layer 5 can therefore be advantageously carried out by well-known and controlled deposition techniques, and of industrial efficiency, allowing in particular to treat the entire front face 20 of the substrate at once.

The deposition 120 of the base layer 5 by depositing a dry film by lamination is preferably carried out under vacuum.

Various dry films based on various polymers are marketed today which can be used according to the manufacturing method 100 of the invention. For example, mention can be made of: the MX5000™ series from DuPont™ or the A2023 film from Nagase Gmbh. The manufacturers of such films generally characterise the parameters which are of interest for the implementation of the method according to the present invention, such as their viscoelastic parameter(s), their deposition parameter(s) and their thickness.

The aforementioned deposition techniques can, by their sole embodiment, bring the base layer 5 to temperature, or even pressure conditions, allowing it 130 to be deformed, in particular viscoelastically, after the deposition 120, or even including during the deposition 120.

Alternatively or in addition, it is considered to subject at least the base layer 5 to a sufficient temperature, or even to a controlled surrounding pressure, to induce its viscoelastic deformation, or else also its plastic deformation.

More particularly, the base layer 5 is either deposited solid, before being heated, or deposited “hot”. The couple [temperature T, time t] of the deformation of the base layer 5 is selected so as to allow to fill, if necessary partially, the spaces 4. The higher the temperature, the shorter the filling time, this time can vary from 1 min to a few hours, even 1 day or a few days. A temperature of at least 10° above the glass transition temperature T_{g} will be selected (to induce the viscoelastic deformation). Advantageously, a temperature T between 10 and 40° C. above the glass transition temperature T_{g} will be selected, but it is possible to go beyond this insofar as there is no degradation of the material of the base layer 5 and/or the substrate. For the highest temperatures, rather a viscous flow will be obtained (but the viscous flow remains comprised in the viscoelastic deformations).

Furthermore, as indicated above, the step of depositing 120 the base layer 5 and the step of allowing 130 the material of the base layer 5 to at least partially fill the at least one of the spaces 4, preferably all the spaces, defined between the reliefs of the same plurality by an at least viscoelastic deformation of the base layer 5, can be carried out under different pressure conditions. More particularly, while the deposition step 120 is preferably carried out under vacuum, step 130 can, in turn, be carried out at a higher pressure, and in particular at ambient pressure. This step 130 can be carried out under a flow of compressed air or nitrogen. Thus, an air pressure differential between the second face 50 of the base layer 5, this second face 50 defining the free surface of the base layer 5, and the first face of the base layer 5 located facing the front face 20 of the substrate 2 is created. This differential assists the viscoelastic deformation of the free surface 50 of the base layer 5.

Thus, the step of allowing 130 the material of the base layer 5 to at least partially fill the at least one of the spaces 4, preferably all the spaces, defined between the reliefs 3 of the same plurality by an at least viscoelastic deformation of the base layer 5 may or may not require a positive action (a rise in temperature in particular). This need or its absence is to be determined at least according to the viscoelastic parameters, the deposition parameters and the thickness of the base layer 5. When no positive action is required, it is sufficient to allow the base layer 5 as deposited 120 to evolve freely and naturally for a certain time.

Typically, the temperatures to be considered are comprised between −20° C. and 400° C., and more particularly comprised between 20° C. and 200° C., for polymers. They are comprised between 300° C. and 700° C. for glass (depending on their composition). It should also be noted that the shape of the pattern 6, before reaching the balance of the surface tensions involved, changes over time in a very dependent manner on the temperature to which the base layer 5 is subjected: generally, the higher the temperature, the faster the change in the shape of the pattern 6.

As stated above, the filling of the spaces 4 defined between the reliefs of the plurality of reliefs 3 structuring the front face 20 of the substrate 2 is related to the deformation, which is in particular viscoelastic, of the base layer 5, which flows into the spaces 4 left free between the reliefs 3.

FIG. 3C shows a situation wherein the base layer 5 has flowed so as to partially fill each of the cavities 41. It is illustrated in this figure that the direct consequence of this filling is a continuous deformation of the face (or free surface) 50 of the base layer 5 opposite to that located opposite the substrate 2. This continuous deformation of the free surface 50 of the base layer 5 comprises a pattern 6 which is curved at least in line with the reliefs 31. It is this pattern 6, the shape of which advantageously has an aspherical, low, or even very low curvature. It is also this pattern 6 which ultimately defines the shape and the curvature 11 of the microlens 10 such as that illustrated in FIG. 2.

Several observations immediately appear as to the deformation of the free surface 50 of the layer 5.

First, the free surface 50 must remain continuous; its deformation must not lead to its rupture. To ensure this, the thickness of the layer 5, the temperature to which it is brought to be deformed and/or the time that is left for the base layer 5 to be deformed are all parameters to be taken into consideration.

It also appears, in particular by comparing FIGS. 3C and 3D, that the shape, and in particular the sweep f (or the depth), of the pattern 6 formed depends on the degree of filling of the spaces 4. It is possible to observe the deformation of the free surface 50 of the base layer 5 so as to interrupt it when this deformation has led to the generation of a pattern 6 of the desired shape. It is also possible to allow the material of the base layer 5 to flow so that it completely fills the spaces 4. In this case, the thickness of the base layer 5 as deposited must be sufficient relative to the volume represented by the spaces 4. The free surface 50 of the layer 5 takes a particular and stable shape, the curvature of which is determined by the surface tensions involved.

Whether one proceeds by balancing the surface tensions involved or by interrupting the deformation at a selected moment before stabilisation, the curvature of the pattern 6 formed depends at least on the viscoelastic, or else plastic parameters of the base layer 5. To some extent, these parameters in turn depend on the deposition parameters of the base layer 5.

From these considerations, it follows that, for each plurality of reliefs 3, the number, shape and spatial distribution of the reliefs 3 are to be configured at least according to the viscoelastic, or else plastic parameters and to the deposition parameters of the base layer 5. It is the set of these parameters which determines the curvature of the formed pattern 6 whether it is stabilised or not.

It is also possible to play on the composition of the base layer 5: thus the base layer 5 can consist not of a single layer but of a stack of two or more layers of different materials selected from glass and polymers and whose properties among which at least one of their thickness and their glass transition temperature T_{g} are different. Thus, a considerably increased number of possibilities for implementing the method is obtained, for adaptation to each need and each objective, in particular in terms of curvature and/or size of the pattern. Indeed, it is possible to optimise, by simulation or empirically, the various method parameters: choice of materials, thicknesses of the layers, temperature and pressure, etc., to induce the deformation. Advantageously, the layers flowing the least (viscoelastic, even viscous) will be placed at the bottom of the stack (that is to say on the side of the front face 20 of the substrate 2), and the more elastic layer(s) on top of the stack.

Whether one proceeds by balancing the surface tensions or by interrupting the deformation at a selected moment, it is preferable that the free surface 50 of the base layer 5 is sufficiently stiff or stiffened to maintain its shape. For the production of a master, it is preferable that the free surface 50 of the base layer 5 is sufficiently stiff or stiffened to allow the subsequent manufacture of a mould.

The deposition parameters 120 of the base layer 5, as well as the temperature, or else pressure parameters wherein the base layer 5 is maintained during the filling of the spaces 4 (the latter parameters being able to change over time) influence the more or less stiff state of the free surface 50 of the base layer 5, once the balance of the surface tensions has been reached or when the deformation is interrupted. This stiffness may be sufficient to ensure that the shape of the pattern 6 formed is maintained. Otherwise, the method 100 may further comprise, once the pattern 6 has been formed, a step of stiffening, at least on the surface, the base layer.

When the material of the base layer 5 is a polymer, the stiffening step can comprise providing the polymer, at least on the surface of the base layer 5, in a glassy, solid or rubbery state. The crosslinking of the polymer can be obtained either by application of a luminous flux, for example by UV (ultra-violet) treatment, or by heat treatment. When the viscoelastic material is glass, the stiffening step can comprise bringing the glass, at least to the surface of the base layer, into a glassy state. When a stiffening step is not necessary, it means that the material of the base layer 5 is already in one of the aforementioned states without the need for positive action.

The pattern 6 of the master 1 as manufactured by implementing the method 100 according to the embodiment which has just been described with reference to FIGS. 3A to 3D is concave in shape.

Other optional steps of the manufacturing method 100 according to the invention are described below, in particular with reference to FIGS. 3E to 3I and 6.

As illustrated in FIGS. 3E to 3G, the manufacturing method 100 according to the invention may further comprise a step of removing 140 the base layer 5 around the pattern 6 formed, so as to expose the portion 22 of the front face 20 of the substrate 2 which is free of reliefs. As illustrated in FIGS. 3E to 3G, this removal step can be carried out by photolithography, the cost of which is here advantageously very low because the patterns 6 have a transverse size greater than 100 μm, or even greater than 1 mm. The removal step can be completed, as shown in FIG. 3H, by removing a residual by etching, with or without an oxide-type mask.

As illustrated in FIG. 3I, the manufacturing method 100 according to the invention may further comprise a step of depositing 150 a finish layer 7 on each pattern 6 and the exposed portion of the front face 20 of the substrate 2, potentially in line with the entire front face 20 of the substrate 2. The finish layer 7 is preferably conformal, so as not to modify the shape of the pattern 6, or even so as not to significantly modify the dimensions of the pattern 6, in particular with regard to the functionality of the object that is desired to be ultimately manufactured. The finish layer 7 is for example based on oxide, and in particular on silicon oxide, in particular when the substrate is itself based on silicon or silicon nitride.

More particularly, the master 1 is thus prepared in additional steps comprising in particular the grafting on the finish layer 7 of non-stick layers and/or the transfer of the pattern 6 in transfer layers generally comprising organic elements and intended to form an intermediate mould. The non-stick layers are provided to prevent unwanted tearing when the transfer layers of the pattern 6 are peeled from the master 1.

Moreover, it is advantageous that the finish layer 7 is based on silicon oxide or silicon nitride because such a layer is impermeable to the organic elements composing the transfer layers; this prevents migration of these organic elements into the structure 1. This is also advantageous because the grafting of non-stick layers is facilitated on this type of material.

At this stage, the master 1 manufactured by implementing the manufacturing method 100 according to the first variation of the invention is prepared in order to manufacture a nanoimprint mould intended for example for the manufacture of microlenses such as the one illustrated in FIG. 2. Alternatively, the mould part manufactured by implementing the manufacturing method 100 according to the second variation of the invention is prepared in order to manufacture, by nanoimprinting, a lens such as that illustrated in FIG. 2.

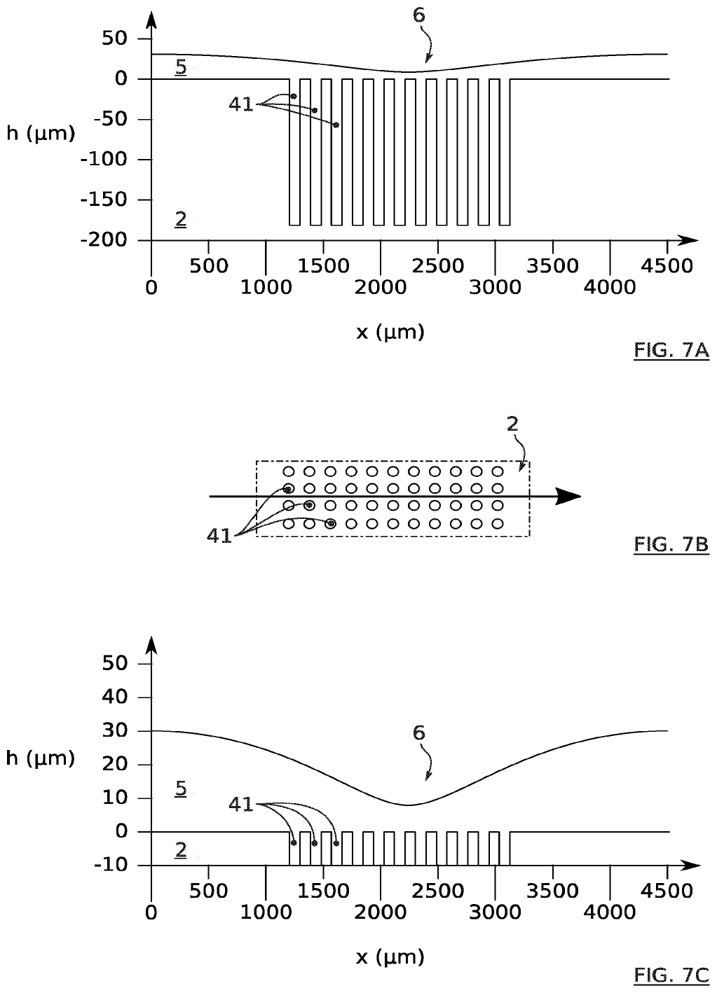

FIGS. 7A to 7C illustrate an example of implementation of the manufacturing method 100 as described above.

FIG. 7A shows a sectional view of the substrate 2 taken transversely to a plurality of reliefs forming cavities 41 therebetween. As illustrated in FIG. 7B, the cavities 41 in fact form a regular paving of holes of circular section formed in the front face 20 of the substrate. The base layer 5 is deformed so as to have a curved pattern 6 in line with and generally beyond the reliefs. The pattern 6 as illustrated in FIG. 7A was taken along the arrow illustrated in FIG. 7B. This pattern 6 was more particularly obtained by depositing a dry film of polymer maintained at 120° C. and under a pressure of 1 atmosphere, for 8 minutes after its deposition by lamination. It can be seen in FIG. 7A, and better still in FIG. 7C which is an enlargement on the ordinate of FIG. 7A, that the curvature of the pattern 6 ends up extinguishing at abscissas 0 and 4500 μm. Thus, a mesh size of a pattern 6 is defined as the transverse extent over which the pattern 6 extends before its curvature is extinguished. In the illustrated example, the mesh size is therefore approximately 4500 μm.

The mesh size can define the extent over which the layer 5 must be deposited, in a centred manner, in line with and beyond the reliefs 3, to avoid undesirable edge effects during the deformation of the base layer 5. When several pluralities of reliefs 3 structure the front face 20 of the substrate 2, the mesh size can further define the distance to be placed between these pluralities to prevent the deformation of the base layer 5 at a plurality from influencing on the deformation of the base layer 5 at any other plurality. Thus, when several pluralities of reliefs structure the front face of the substrate, each plurality should be sufficiently spaced from any other plurality, if it is desired that each plurality define the curvature of the pattern 6 that it generates without any other influence, in a self-controlled manner.

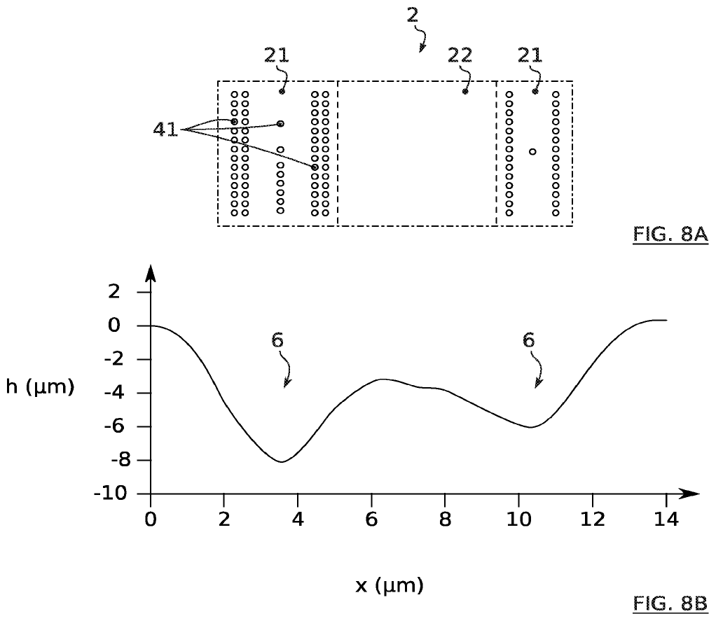

FIGS. 8A and 8B illustrate an example corresponding to that which has just been described with reference to FIGS. 7A to 7C, except that two pluralities of reliefs 3 are here explicitly illustrated, which are not identical to each other and which, as illustrated by the profile measured by a stylus and reproduced in FIG. 8B, are not sufficiently spaced apart so that the pattern 6 formed by means of one does not influence the pattern 6 formed by means of the other of the two pluralities of reliefs 3. Indeed, it can be seen, in FIG. 8B, that the pattern 6 formed by one of the two pluralities of reliefs differs in depth, in curvature and in size from the pattern 6 formed by the other of the two pluralities of reliefs; this illustrates the impact of the number, shape and spatial distribution of the reliefs on the formed pattern 6. It can also be seen from FIG. 8B that the height of the profile between the two patterns 6 is less than the height of the profile on either side of the two patterns; the profiles therefore do not form a bearing of a height substantially equal to the height of the profile on either side of the two patterns, which would have been substantially the case if the pluralities of reliefs had been sufficiently spaced apart so that the two patterns 6 are formed independently of one another.

It should be noted that, if the geometry of the pattern can be controlled by adjusting the reliefs of a plurality and their surface density, it is still possible to compensate for a possible impact of the method at the scale of the substrate. This impact can be related, for example, to a thermal expansion effect or to a volume shrinkage related to the crosslinking of the polymer. The compensation for this impact can be achieved by a local correction of patterns 6 formed from, for example, an empirical study consisting in converging, from trials/errors, to the optimal solution.

Two other embodiments of the method according to the invention will now be described, in terms of what distinguishes them from the embodiment described above, and with reference to FIGS. 4A to 4D, 5A and 5B. In general, these two other embodiments allow to obtain a structure 1 (master, mould part or lens) of convex shape.

FIGS. 4A to 4D are valid to illustrate each of the two embodiments. A plurality of reliefs 3 in the shape of projections on the front face 20 of the substrate 2 appears therein.

The reliefs 3 illustrated in FIG. 4A can be obtained by forming a plurality of cavities 42 in a mesa 43 formed on the front face 20 of the substrate 2, as illustrated in FIG. 5A. The cavities 42 can take a shape and dimensions identical to those of the cavities 41 described above.

According to the embodiment illustrated in FIG. 5B, the reliefs 3 illustrated in FIG. 4A can be obtained by forming a plurality of reliefs 31 on the front face 20 of the substrate 2. The reliefs 31 can take a complementary shape and dimensions which are substantially identical to those of the cavities 41 described above.

Once the structured substrate 2 has been provided 110, as before, the base layer 5 is deposited at least in line with the plurality of reliefs 3.

Unlike the embodiment illustrated in FIG. 5B, the portion of the base layer 5 which extends beyond the plurality of reliefs 3 may not rest on the front face 20 of the substrate 2; this depends in particular on the viscoelastic, or else plastic parameters and on the deposition parameters of the base layer 5. Consequently, the step of allowing the material of the base layer 5 to fill the spaces 4 can further comprise the step of allowing the material of the base layer 5 located in line with the portion 22 of the front face 20 of the substrate which is free of reliefs to contact at least a portion of the front face 20 of the substrate 2. Also, when at least two pluralities of reliefs 3 structure the front face 20 of the substrate 2 by defining second spaces therebetween, the step of allowing 130 the material of the layer 5 to fill the spaces 4 may further comprise the step of allowing the material of the base layer 5 located in line with the second spaces to at least partially fill these second spaces.

Thanks to the method 100 according to the embodiments described above, it is possible to manufacture a master for the manufacture of a mould part, a mould part for nanoimprinting microlenses, and ultimately a lens such as that illustrated in FIG. 2, having in particular an aspherical curvature, and in particular a low (<10⁻² μm⁻¹), or even very low (<10⁻⁶ μm⁻¹) curvature.

The invention exploits the viscoelastic, and potentially also plastic, deformation of a free surface 50 of a base layer 5 based on polymer or glass by filling cavities 41, 42 or spaces defined between the reliefs 31 on which the base layer 5 is deposited 120. The shape, the curvature and the sweep of each pattern 6 formed depend on the density of the cavities 41, 42 and/or reliefs 31, on the viscoelasticity of the base layer 5 and on the deposition parameters of the base layer 5. The volume of material displaced is proportional to the volume of the cavities 41, 42 or of the spaces defined between the reliefs 31, but the shape of the pattern 6 is in turn more related to the density of the cavities 41, 42 and/or reliefs 31 on a given mesh size. The mesh size depends on the materials and conditions under which the method 100 is implemented. If the pattern 6 as generated is of aspherical shape, with low, or even very low curvature, its shape ratio can be further accentuated via an imprinting-etching step on a new substrate. The shape factors then further depend on the etching method and the materials involved. In particular, if the etching selectivity between the resin of the base layer 5 and the substrate is strictly greater than 1, the curvature will be reduced. Conversely, if the etching selectivity between the resin of the base layer 5 and the substrate is strictly less than 1, the curvature will be increased.

The manufacturing method 100 according to the invention allows to manufacture in parallel a plurality of patterns 6 on a substrate 2 in the shape of a wafer eight inches in diameter, or even more, potentially in just a few minutes. When the structure 1 obtained has several patterns 6, it is possible that the latter have been formed so as to have a predetermined relative position with respect to one another. In this case, the structure 1 comprising several patterns 6 can be used as such, for example, when the structure 1 is a master, in order to manufacture a mould allowing the simultaneous nanoimprinting of a plurality of microlenses having said predetermined relative position relative to each other. Alternatively, a structure 1 comprising several patterns 6 can be subjected to a cutting aiming at separating the patterns 6 from each other, for example, when the structure 1 is a master, to use each of them for the manufacture of a mould part and, consequently, in the manufacture of a microlens.

Another aspect of the present invention indeed relates to the use of a master 1 manufactured by implementing the method 100 according to one of the embodiments described above, for the manufacture of at least one nanoimprint mould.

According to another aspect, the invention relates to a method for manufacturing at least one nanoimprint mould by moulding from a master 1 manufactured by implementing the method 100 according to one of the embodiments described above.

According to another aspect, the invention relates to the use of a nanoimprint mould manufactured according to a method for manufacturing at least one nanoimprint mould by moulding from a master 1 manufactured by implementing the method 100 according to one of the embodiments described above, for the manufacture of at least one microlens 10 by nanoimprinting.

The structure 1 produced according to the method 100 of the invention indeed finds application in the manufacture of microlenses or three-dimensional shapes with low, or even very low curvature. The structure 1 can indeed be used as a mould comprising the pattern 6 formed by the method 100 according to the invention. The microlenses or three-dimensional shapes manufactured using such a mould can be made from a permanent polymer transparent to the visible wavelengths for visible imaging or from a polymer used as an etching mask for manufacturing lenses from silicon for applications related to infrared imaging.

It is still possible, thanks to the method 100 according to the invention, to manufacture three-dimensional shapes in a layer of polymer deposited on a reflective substrate to make reflection optics. The use of a non-reflective substrate to make reflection optics is also considered by providing to cover it with a thin reflective layer (which is typically metallic, for wavelengths in the visible, for example).

It is also possible, thanks to the method 100 according to the invention, to manufacture curved substrates which can be used as a handle to transfer flexible components requiring a certain curvature thereon in order to have an optimal or improved operation. This is for example the case with imagers or video sensors, such as CCD (for “Charge-Coupled Device”) sensors, thus allowing to have curved detectors. The curvature is then induced by the support substrate manufactured with the method 100 according to the invention. Furthermore, the manufacture of the sensor can be made on a flat substrate, the sensor then being transferred on the support substrate. This can allow to relieve some stresses in the manufacture of the sensor, and in particular some stresses in the manufacture of the optics associated with the sensor, which no longer necessarily needs to be curved.

The invention is not limited to the embodiments previously described and extends to all embodiments covered by the claims.

For example, if the figures illustrate reliefs 31 and cavities 41 which are all identical, whether for the same plurality or different pluralities of reliefs 31 and cavities 41, 42, it is understood that the reliefs 31 and the cavities 41, 42 may be of various shapes and sizes, whether within the same plurality or from one plurality to another.

For example, the reliefs 31 and the cavities 41, 42 of the same plurality may have different heights or depths. This allows great freedom in the shape of the pattern 6 obtained in the end.

For example, the cavities 41, 42 and/or the reliefs 31 can form concentric rings of diameters which are different from each other.

1. A method for producing (100) a structure having at least one curved pattern, for example to manufacture a master for a nanoimprint mould, the method comprising:
providing a substrate having a front face whereof:
one portion is structured by at least one plurality of reliefs, the reliefs of each plurality defining therebetween at least one space, and
another portion is free of reliefs,
depositing a base layer of a material based on one of a polymer and a glass, over the entire front face of the substrate, at least in line with the reliefs, the base layer having a first face facing the front face of the substrate and a second face opposite the first face, and
allowing the material of the base layer to at least partially fill the at least one space defined between the reliefs of the same plurality by deformation of the base layer,
the base layer being thus deformed so that its second face remains continuous over the entire front face of the substrate and forms a structure having at least one curved pattern in line with the at least one space which is at least partially filled with the material of the base layer.

2. The method according to claim 1, wherein the deposition 120 of the base layer is carried out under vacuum, and wherein the step of at least partially filling the at least one space defined between the reliefs of the same plurality is carried out at ambient pressure, preferably under a flow of compressed air or nitrogen.

3. The method according to claim 1, wherein, for each plurality of reliefs, the number, shape and spatial distribution of the reliefs are configured at least depending on viscoelastic or plastic parameters of the base layer and deposition parameters of the base layer.

4. The method according to claim 1, wherein the step of at least partially filling the at least one space defined between the reliefs of the same plurality comprises the following step:
completely filling each space until a pattern, the curvature of which is determined by balancing the surface tensions involved, is generated.

5. The method according to claim 1 wherein the step of at least partially filling the at least one space defined between the reliefs of the same plurality may comprise a rise in temperature, at least 10°, preferably between 10 and 40° C., above the glass transition temperature Tg of the material from which the base layer is made.

6. The method according to claim 1 wherein the at least one plurality of reliefs defines at least one cavity formed in the front face of the substrate.

7. The method according to claim 1, wherein the at least one plurality of reliefs comprises a mesa formed on the front face of the substrate and wherein the at least one space comprises at least one cavity formed in the mesa.

8. The method according to claim 1, wherein the at least one plurality of reliefs comprises a relief protruding from the front face of the substrate.

9. The method according to claim 1, further comprising, once said at least one pattern has been formed, the following step:
stiffening, at least on the surface, the base layer, the stiffening step comprising, where appropriate, a corresponding one from:
providing the polymer, at least on the surface of the base layer, in a glassy, solid or rubbery state, and
providing the glass, at least on the surface of the base layer, in a glassy state.

10. The method according to claim 1, further comprising, once said at least one pattern has been formed, the following steps:
removing the base layer around each formed pattern, so as to expose the portion of the front face of the substrate which is free of reliefs, then
depositing a finish layer over each pattern and the exposed portion of the front face of the substrate.

11. The method according to claim 1, wherein the at least one plurality of reliefs defines a cavity and/or comprises at least one relief having at least one of:
a depth or height greater than 10 μm, preferably greater than 100 μm and
at least one transverse dimension comprised between 20 and 200 μm, preferably comprised between 50 and 100 μm.

12. The method according to claim 1, wherein the at least one space defined between the reliefs of each structured portion of the front face of the substrate occupies at least half of the surface of this structured portion.

13. The method according to claim 1, wherein the step of depositing the base layer is configured so that the base layer has, preferably before its deformation, a thickness comprised between 20 and 200 μm.

14. The method according to claim 1, wherein the step of depositing the base layer comprises one of the steps of:
depositing a dry film by lamination, and
depositing a solution comprising the material of the base layer by centrifugal coating.

15. The method according to claim 1, wherein the at least one plurality of reliefs comprises several pluralities of reliefs spaced apart by the portion of the front face of the substrate which is free of reliefs, each plurality of reliefs being intended for the formation of a pattern.

16. The method according to claim 15, wherein the at least one of said portion of the front face of the substrate which is free of reliefs and the step of depositing the base layer is configured so that the deformation of the base layer at each plurality of reliefs does not influence the deformation of the base layer at any other plurality of reliefs.

17. The method according to claim 1, wherein the structure is a master for forming a nanoimprint mould.

18. The method according to claim 1, wherein the structure is a part of a nanoimprint mould.

19. The method according to claim 1, wherein the structure is a lens.

20. A method for manufacturing at least one nanoimprint mould using a master manufactured by implementing the method according to claim 1.

21. A method for producing at least one microlens by nanoimprinting, using a nanoimprint mould manufactured by transferring at least one pattern from a master, the master being manufactured by implementing the method according to claim 1.
